(19) United States
(12) Patent Application Publication
(10) Pub. No.: US 2024/0337011 A1
(43) Pub. Date: Oct. 10, 2024

(54) MULTIFUNCTIONAL WAFER PRETREATMENT CHAMBER AND CHEMICAL VAPOR DEPOSITION DEVICE

(71) Applicant: Betone Technology Shanghai, Inc., Shanghai (CN)

(72) Inventors: Yongjun FENG, Shanghai (CN); Dongping ZHOU, Shanghai (CN); Weicong SONG, Shanghai (CN)

(73) Assignee: Betone Technology Shanghai, Inc., Shanghai (CN)

(21) Appl. No.: 18/699,307

(22) PCT Filed: Sep. 22, 2022
(86) PCT No.: PCT/CN2022/120453

§ 371 Date: Apr. 8, 2024

(30) Foreign Application Priority Data
Dec. 29, 2021 (CN) 202111625163.5

(51) Int. Cl. C23C 16/02; C23C 16/458; C23C 16/46; C23C 16/48; C23C 16/52

(52) U.S. Cl. CPC C23C 16/0209; C23C 16/4586; C23C 16/463; C23C 16/482; C23C 16/52

(57) ABSTRACT

A multifunctional wafer pretreatment chamber and a chemical vapor deposition device. The pretreatment chamber comprises a cavity, wafer carrier device, preheating device, thermal conductive device, cooling device, first driving device, second driving device, and controller. The wafer carrier device comprises a carrier tray and supporting pins. The thermal conductive device is located below the preheating device and above a wafer, and comprises a thermal conductive plate and a thermal insulation coating. Thermal conductive holes are distributed on the thermal conductive plate. The preheating device comprises a lamp plate and heating lamps. The heating lamps are fixed to the plate-surface portion. The cooling device comprises a cooling pipe, and is in communication with a cooling source. The controller is connected to the first driving device and the second driving device, and the latter two are for a preheating mode and a cooling mode respectively.

### FIELD OF THE INVENTION

The present disclosure relates to the technical field of semiconductor manufacturing, in particular, to a multifunctional wafer pretreatment chamber and a chemical vapor deposition device.

### BACKGROUND OF THE INVENTION

Chip manufacturing involves multiple repetitions of film deposition, photoresist coating, exposure and development, etching, ion implantation, and so on. Some of these steps require high temperatures above 200° C., such as chemical vapor deposition (CVD) which can reach 400-500° C. During CVD, the wafer is rapidly heated to 400-500° C. in the process chamber, and usually the center of the wafer heats up faster than the edge, resulting in uneven warpage of the wafer. As the deposition continues, the film thickness increases, and the warpage area causes an imbalance of weight distribution due to different film thicknesses, leading to wafer sliding and mechanical arm picking failures, among other issues. Therefore, it is crucial to preheat the wafer before it enters the reaction chamber.

Most of the existing wafer heating or preheating devices utilize the method of heating the wafer on a heated base (i.e., heating a lower surface of the wafer by the base). This method heats the wafer up quickly and can shorten the heating time, but it is costly and consumes more power. However, in the current process, the preheating stage does not need immediate heating, and the wafer to be preheated can slowly and evenly heat up during the time when the previous wafer is undergoing film deposition. Therefore, how to ensure the uniform heating of the wafer during the preheating stage, while reducing the power consumption and manufacturing costs of devices, is a problem that needs constant exploration and improvement. Moreover, after the film deposition is finished, physical cooling is also needed. The existing technology cools the wafer in a cooling chamber that is separate from the preheating chamber and the process chamber. Therefore, the existing CVD devices have a large overall size, occupy a lot of space, and because the preheating and cooling chambers are independent, the chamber utilization rate is low, resulting in low device efficiency and high manufacturing costs.

### SUMMARY OF THE INVENTION

In view of the shortcomings of the related technologies, the present disclosure provides a multifunctional wafer pretreatment chamber and a chemical vapor deposition device, for addressing issues prevalent in the related technologies.

The multifunctional wafer pretreatment chamber comprises a cavity, a wafer carrier device, a preheating device, a thermal conductive device, a cooling device, a first driving device, a second driving device, and a controller. The cavity is provided with at least one gate. The wafer carrier device is located in the cavity and comprises a carrier tray and a plurality of supporting pins, the carrier tray is provided with a plurality of containing holes, and each of the plurality of supporting pins is disposed in one of the plurality of containing holes. The first driving device is connected with the plurality of supporting pins for driving each of the plurality of supporting pins to ascend or descend in the corresponding containing hole as required. Thermal conductive device is located below the preheating device and above a wafer to be treated, and the thermal conductive device comprises a thermal conductive plate and a thermal insulation coating. Dimensions of the thermal conductive plate are consistent with those of the wafer, a plurality of thermal conductive holes are distributed on the thermal conductive plate at intervals, the plurality of thermal conductive holes penetrate the thermal conductive plate, and the thermal insulation coating covers surfaces of the thermal conductive plate not penetrated by the heat conduction holes. The preheating device comprises a lamp plate and two or more heating lamps, the lamp plate comprises a plate-surface portion and a shielding portion, the heating lamps are fixed to a bottom surface of the plate-surface portion, a first end of the shielding portion is connected with an edge of the plate-surface portion, and a second end of the shielding portion extends to be in contact with an edge of the thermal conductive plate. The second driving device is connected with the lamp plate and configured to drive the preheating device to rotate. The cooling device comprises a cooling pipe located in the carrier tray, and the cooling device is in communication with a cooling source. The controller is connected to the first driving device and the second driving device, wherein when the multifunctional wafer pretreatment chamber is in a preheating mode, the first driving device drives the supporting pins to ascend to support the wafer under the control of the controller, the preheating device is started, and light emitted by the heating lamps reaches a surface of the wafer through the thermal conductive holes, so as to heat the wafer; and when the multifunctional wafer pretreatment chamber is in a cooling mode, the first driving device drives the supporting pins to descend under the control of the controller, the wafer is placed on the carrier tray, and the cooling device is started.

Optionally, a surface of the lamp plate facing the thermal conductive plate and/or a surface of the shielding portion adjacent to the heating lamps is provided with a reflective thermal insulation coating.

Optionally, the at least one gate comprises a first gate and a second gate, and the controller is connected to the first gate and the second gate; wherein when the wafer enters the cavity through the first gate, the controller controls the preheating device to start and the supporting pins to ascend, and when the wafer enters the cavity through the second gate, the controller controls the cooling device to start and the supporting pins to descend.

Optionally, a groove is formed in the carrier tray, a cooling pipe is disposed on a side surface and a bottom surface of the groove, and the wafer to be treated is placed in the groove.

Optionally, a top surface of each supporting pin is an inclined surface, and when the multifunctional wafer pretreatment chamber is in the preheating mode, the top surface of each supporting pin is in contact with an edge of the wafer.

Optionally, the multifunctional wafer pretreatment chamber further comprises a third driving device connected to the carrier tray and electrically connected to the controller, and configured to drive the carrier tray to reciprocatively rotate and/or ascend and/or descend.

Optionally, the multifunctional wafer pretreatment chamber further comprises a temperature measuring device, which is located in the cavity and electrically connected with the controller; wherein the controller is electrically connected with the heating lamps, and when the temperature measuring device detects that temperatures in different surface areas of the wafer are different, the controller is configured to adjust power of the heating lamps, respectively.

Optionally, the multifunctional wafer pretreatment chamber further comprises an auxiliary thermal insulation device and a fourth driving device connected with the auxiliary thermal insulation device; wherein the auxiliary thermal insulation device is located in the cavity, the fourth driving device is electrically connected with the controller, and when the multifunctional wafer pretreatment chamber is in the preheating mode, under the control of the controller, the fourth driving device drives the auxiliary thermal insulation device to wrap around a space between the thermal conductive device and the carrier tray to prevent heat loss.

The chemical vapor deposition device comprises at least one chemical vapor deposition chamber and a multifunctional wafer pretreatment chamber according to any one of the above embodiments, wherein the chemical vapor deposition chamber is connected with the multifunctional wafer pretreatment chamber.

Optionally, the at least one chemical vapor deposition chamber comprises two or more chemical vapor deposition chambers.

As described above, the multifunctional wafer pretreatment chamber and the chemical vapor deposition device of the present disclosure have the following beneficial effects: the improved structural design of the present disclosure integrates the heating and cooling functions in different locations within the same chamber. Therefore, the device functions are more integrated, and the interference (such as the heat spreading from the heating area to the cooling area) between the two functions is minimized. This improves the wafer heating and cooling efficiency, increases the device output, and reduces the power consumption and manufacturing costs of devices. Moreover, the improved structural design also enhances heating uniformity, and reduces the problems of wafer warping, uneven film deposition thickness, wafer deformation and slippage caused by uneven heating.

### BRIEF DESCRIPTION OF DRAWINGS

FIG. 1 shows a schematic structural diagram of a multifunctional wafer pretreatment chamber of the present disclosure.

FIG. 2 shows a schematic diagram showing the partial structure of a thermal conductive plate shown in FIG. 1.

FIG. 3 shows a schematic diagram showing the partial structure of a preheating device of the present disclosure.

### REFERENCE NUMERALS

11—Cavity; 111—First gate; 112—Second gate; 12—Carrier tray; 13—Supporting pins; 14—Thermal conductive plate; 15—Thermal insulation coating; 16—Thermal conductive holes; 17—Wafer; 18—Lamp plate; 181—Plate-surface portion; 182—Shielding portion; 19—Heating lamps; 20—Rotating shaft; 21—Motor; 22—Auxiliary thermal insulation device; 23—Cooling pipe.

### DETAILED DESCRIPTION OF THE INVENTION

The embodiments of the present disclosure will be described below. Those skilled can easily understand disclosure advantages and effects of the present disclosure according to contents disclosed by the specification. The present disclosure can also be implemented or applied through other different exemplary embodiments. Various modifications or changes can also be made to all details in the specification based on different points of view and applications without departing from the spirit of the present disclosure. When describing the embodiments of the present disclosure, for better explanation, cross-sectional structural diagrams may be partially enlarged without following the general scale. Moreover, the diagrams are only examples and should not limit the scope of the present disclosure. In addition, the actual production should comprise the length, width and depth of the three-dimensional space dimensions.

For the convenience of description, spatial relation terms such as “below”, “under”, “beneath”, “on”, “above”, “up”, etc. may be used herein to describe the relationships between an element or feature and other elements or features. It will be understood that these spatial relationship terms are intended to encompass directions/orientations of the device in use or operation other than those depicted in the drawings. In addition, when a first layer is referred to as being “between” a second layer and a third layer, the first layer may be the only layer between the second and third layers, or there may more layers between the two layers.

In the context of this disclosure, the structure described with a first feature “on top” of a second feature may include embodiments where the first and second features are formed in direct contact, or it may include embodiments where additional features are formed between the first and second features such that the first and second features are not in direct contact.

It should be noted that the drawings provided in this disclosure only illustrate the basic concept of the present disclosure in a schematic way, so the drawings only show the components closely related to the present disclosure. The drawings are not necessarily drawn according to the number, shape and size of the components in actual implementation; during the actual implementation, the type, quantity and proportion of each component can be changed as needed, and the components' layout may also be more complicated. To make the illustration as concise as possible, not all structures are marked in the drawings.

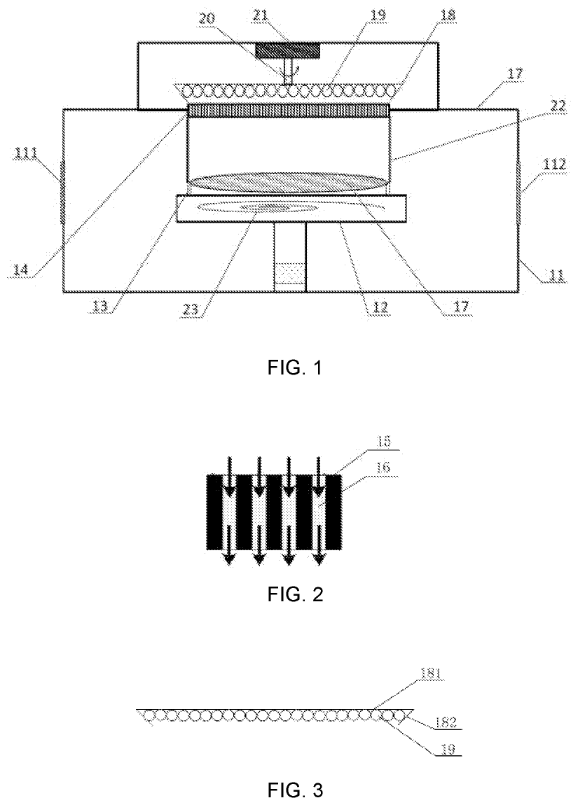

As shown in FIGS. 1-3, the present disclosure provides a multifunctional wafer pretreatment chamber, comprising: a cavity 11, a wafer carrier device, a preheating device, a thermal conductive device, a cooling device, a first driving device, a second driving device, and a controller. The cavity 11 is provided with at least one gate through which a wafer to be treated enters or exits the cavity 11. The wafer carrier device is located in the cavity 11 and comprises a carrier tray 12 and a plurality of supporting pins 13, the carrier tray 12 is provided with a plurality of containing holes, and each of the plurality of supporting pins 13 is disposed in one of the plurality of containing holes. The first driving device is connected with the plurality of supporting pins 13 for driving each of the plurality of supporting pins to ascend or descend in the corresponding containing hole as required. The thermal conductive device is located below the preheating device and above the wafer 17 to be treated, and the thermal conductive device comprises a thermal conductive plate 14 and a thermal insulation coating 15. Dimensions of the thermal conductive plate 14, such as radius, are consistent with those of the wafer 17, a plurality of thermal conductive holes 16 are distributed on the thermal conductive plate 14 at intervals, the plurality of thermal conductive holes 16 penetrate the thermal conductive plate 14, and the thermal insulation coating 15 covers surfaces of the thermal conductive plate 14 not penetrated by the heat conduction holes 16 (preferably covering an upper surface and a lower surface at the same time). The preheating device comprises a lamp plate and two or more heating lamps 19, the lamp plate 18 comprises a plate-surface portion 181 and a shielding portion 182, the heating lamps 19 are fixed to a bottom surface of the plate-surface portion 181, a first end of the shielding portion 182 is connected with an edge of the plate-surface portion 181, and a second end of the shielding portion 182 extends to be in contact with an edge of the thermal conductive plate 14, and the shielding portion 182 prevents light of the heating lamps 19 (bulbs or tubes) at the peripheral of the lamp plate 18 from being directed towards areas of the thermal conductive plate 14 that are not intended to be heated by light, thereby preventing the waste of light and heat, and ensuring that the thermal conductive plate 14 receives sufficient light intensity.

The second driving device is connected with the lamp plate 18 and configured to drive the preheating device to rotate. Preferably, the preheating device rotates reciprocatively to avoid the winding of electrical wires. The second driving device drives the rotation of the lamp plate 18, which in turn drives the rotation of the heating lamps 19, so as to uniformly heat the wafer 17. The second driving device may comprise a rotating shaft 20 and a motor 21 electrically connected with the rotating shaft 20. The rotating shaft 20 and the plate-surface portion 181 may have the same rotation axis, and preferably the rotation axis vertically passes through a center of the wafer 17.

The cooling device comprises a cooling pipe 23 located in the carrier tray 12 (which may also be defined as a cooling tray), and the cooling device is in communication with a cooling source for cooling the wafer 17 as needed.

The controller is connected to the first driving device and the second driving device.

When the multifunctional wafer pretreatment chamber is in a preheating mode, the first driving device, under the control of the controller, drives the supporting pins 13 to ascend to support the wafer 17, the preheating device is started, and light emitted by the heating lamps 19 reaches a surface of the wafer 17 through the thermal conductive holes 16, so as to heat the wafer 17. That is, the thermal conductive plate 14 is used to guide the light to avoid unnecessary photo-thermal dissipation to undesirable areas. Therefore, thermal conductive plates 14 with different thermal conductive holes 16 (e.g., different arrangements, different sizes, etc.) may be adopted as needed, to ensure that the wafer 17 can be precisely heated, which helps to improve the heating efficiency and uniformity.

When the multifunctional wafer pretreatment chamber is in a cooling mode, the first driving device drives, under the control of the controller, the supporting pins 13 to descend, the wafer 17 is placed on the carrier tray 12, and the cooling device is started.

The improved structural design of the present disclosure integrates the heating and cooling functions in different locations within the same chamber. Therefore, the device functions are more integrated, and the interference between the two functions (such as the heat spreading from the heating area to the cooling area) is minimized. After preheating of the previous wafer is completed, the next wafer can be immediately cooled, thereby improving the wafer heating and cooling efficiency, increasing the device output, and reducing the power consumption and manufacturing costs of devices. Moreover, the improved structural design also enhances heating uniformity, and reduces the problems of wafer warping, uneven film deposition thickness, wafer deformation and slippage caused by uneven heating. The multifunctional wafer pretreatment chamber and the process chamber (including but not limited to a chemical vapor deposition chamber) of the present disclosure can be used together. By doing so, the preheating and cooling processes that were originally done in the process chamber can be moved to the multifunctional wafer pretreatment chamber. This can reduce the wafer's dwell time in the process chamber and increase the device's output.

Parameters such as the material and thickness of the thermal conductive plate 14 may be set as needed. For example, the thermal conductive plate 14 may be made of a heat-insulating glass-fiber material, the thickness of the thermal conductive plate 14 is 2-5 cm (including both endpoints), and the thermal conductive holes 16 may vertically penetrate the thermal conductive plate 14 or penetrate the thermal conductive plate 14 at a certain angle. The thermal insulation coating 15 may be, for example, a composite magnesium aluminum silicate thermal insulation coating, with a thickness of 2-10 mm. It is difficult for light and heat to pass through a region covered with the thermal insulation coating 15, and they can only be conducted through the thermal conductive holes 16.

The distribution of the thermal conductive holes 16 may be determined based on the wafer to be heated, and dimensions of the thermal conductive holes 16 may also be set as needed, for example, their apertures vary from 0.1-0.5 mm. For example, when the wafer is a bare wafer with a surface not plated with any coating, a plurality of thermal conductive holes 16 which are consistent in dimension and are uniformly distributed at intervals may be formed in the thermal conductive plate 14. When the surface of the wafer is plated with the coating, according to the condition of the coating, such as the situation where the metal coating plated previously is thicker in the center area and thinner in the edge area, and considering that metals heat up faster when heated, a relatively large number of thermal conductive holes 16 may be disposed in the center area of the thermal conductive plate 14 and a relatively small number of thermal conductive holes 16 may be disposed in the edge area. In one embodiment, the configuration of the thermal conductive holes 16 is not specifically limited. Importantly, by utilizing the thermal conductive plate 14 with the thermal conductive holes 16 and the thermal insulation coating 15, the wafer can be heated more precisely, thereby effectively reducing heat loss, and particularly, avoiding the heat spreading from the heating area to the cooling area as much as possible, so as to minimize the interference to the cooling area, effectively improving the heating and cooling efficiency and reducing the power consumption.

In one embodiment, the heating lamps 19 are uniformly distributed on a lower surface of the plate-surface portion 181, the heating lamps 19 may be halogen lamps, and different heating lamps 19 may be controlled by the same switch or different switches.

In one embodiment, a surface of the lamp plate 18 facing the thermal conductive plate 14 and/or a surface of the shielding portion 182 adjacent to the heating lamps 19 is provided with a reflective thermal insulation coating. Preferably, both surfaces are coated with the reflective thermal insulation coating. The reflective thermal insulation coating does not absorb heat, so as to further avoid heat loss and improve heating efficiency.

The cooling medium in the cooling pipe 23 may be a liquid or a gas, or may be a gas-liquid mixture, and in a preferred embodiment, a phase-change material may also be utilized for rapid heat dissipation.

In one embodiment, the at least one gate comprises a first gate 111 (which may also be defined as a preheating port) and a second gate 112 (which may also be defined as a cooling port), and the controller is connected to the first gate 111 and the second gate 112. When the wafer enters the cavity 11 through the first gate 111, the controller controls the preheating device to start and the supporting pins 13 to ascend, and when the wafer enters the cavity 11 through the second gate 112, the controller controls the cooling device to start and the supporting pins 13 to descend. The multifunctional wafer pretreatment chamber may be connected to a wafer loadport through the first gate 111, and connected to a process chamber through the second gate 112. The process chamber may be a chemical vapor deposition chamber. Specifically, after the wafer to be treated enters the cavity 11 from the wafer loadport through the first gate 111, the preheating device is automatically started, and after the treated wafer enters the cavity 11 from the process chamber through the second gate 112, the cooling device is automatically started, so that the automation degree of devices can be further improved.

In one embodiment, a groove is formed in the carrier tray 12, a cooling pipe are disposed on a side surface and a bottom surface of the groove, and the wafer to be treated is placed in the groove. Therefore, during the cooling process, the cooling pipe can cool the wafer from its side and bottom surfaces at the same time, which helps to improve cooling efficiency, and particularly helps to rapidly cool the edge area of the wafer, thereby avoiding edge warping and/or detachment of film edges from the wafer surface.

In one embodiment, the number of supporting pins 13 is two or more and is usually three or more. The supporting pins 13 are evenly spaced at the edge of the wafer, a top surface of each supporting pin 13 is an inclined surface, and when the multifunctional wafer pretreatment chamber is in the preheating mode, the top surface of each supporting pin 13 is in contact with the edge of the wafer, so that damage to the wafer caused by edges of the supporting pins 13 can be effectively avoided. By utilizing the supporting pins 13, the wafer is away from the carrier tray 12 as far as possible, and heat on the wafer is prevented from being directly conducted to the carrier tray 12.

In one embodiment, the multifunctional wafer pretreatment chamber further comprises a third driving device connected to the carrier tray 12 and electrically connected to the controller, and configured to drive the carrier tray 12 to reciprocatively rotate and/or ascend and/or descend, which helps to further improve the heating and cooling efficiency and avoid the interference of different functions.

In one embodiment, the multifunctional wafer pretreatment chamber further comprises a temperature measuring device (not shown), which is located in the cavity 11 and electrically connected with the controller. The controller is electrically connected with the heating lamps 19, and when the temperature measuring device detects that temperatures in different surface areas of the wafer are different, the controller is configured to adjust power of the heating lamps, respectively, which helps to further enhance the heating uniformity. That is, in this case the power of the various heating lamps will be adjusted in a differentiated manner so that the temperatures in different surface areas of the wafer are uniform.

In one embodiment, the multifunctional wafer pretreatment chamber further comprises an auxiliary thermal insulation device 22 and a fourth driving device connected with the auxiliary thermal insulation device 22. The auxiliary thermal insulation device 22 is located in the cavity 11, the fourth driving device is electrically connected with the controller, and when the multifunctional wafer pretreatment chamber is in the preheating mode, under the control of the controller, the fourth driving device drives the auxiliary thermal insulation device 22 to wrap around a space between the thermal conductive device and the carrier tray 12 to prevent heat loss. After the heating function is finished, the auxiliary thermal insulation device 22 can be automatically removed from the above of the carrier tray 12, so that interference to the movement of the wafer is avoided. A self-cooling device may be further disposed in the auxiliary thermal insulation device 22, and after the preheating process is finished, the auxiliary thermal insulation device 22 starts a self-cooling function so as to minimize a spread of residual heat in the auxiliary thermal insulation device 22 to other areas within the cavity 11, in particular to the vicinity of the cooling device.

An exemplary working process of the multifunctional wafer pretreatment chamber of the present disclosure is to switch between the preheating mode and cooling mode through the controller based on different in/out states of the wafers. The detailed process is as follows:

When the wafer enters the cavity 11 from the first gate 111 (or preheating port), the preheating mode is activated. In the preheating mode, the cooling device is turned off, and the preheating device is started. Specifically, the cooling medium in the cooling pipe 23 stops flowing, the supporting pins 13 support the wafer, all heating lamps 19 in the lamp plate 18 are turned on, the second driving device drives the rotating shaft 20 and the lamp plate 18 to reciprocatively rotate, and light emitted by the heating lamps 19 is uniformly and vertically incident on an upper surface of the wafer through the thermal conductive holes 16 of the thermal conductive plate 14, realizing the uniform preheating of the wafer.

When the wafer enters the cavity 11 from the second gate 112 (or cooling port), the cooling mode is activated. In the cooling mode, the preheating device is turned off, and the cooling device is started. Specifically, the rotating shaft 20 stops rotating, the heating lamps 19 are turned off, the supporting pins 13 descend below an upper surface of the carrier tray 12 and the wafer is placed on the upper surface of the carrier tray 12, and the cooling medium in the cooling pipe 23 circularly flows to cool the wafer.

The present disclosure further provides a chemical vapor deposition device, comprising: at least one chemical vapor deposition chamber and a multifunctional wafer pretreatment chamber according to any one of the above embodiments. The chemical vapor deposition chamber is connected with the multifunctional wafer pretreatment chamber. For more detailed description of the multifunctional wafer pretreatment chamber, please refer to the foregoing content, which will not be repeated here. The chemical vapor deposition device of the present disclosure can preheat and cool the wafer within the multifunctional wafer pretreatment chamber, allowing the chemical vapor deposition chamber to focus on the chemical vapor deposition process. This improves the utilization rate of the process chamber and increases the device output. In addition, the multifunctional wafer pretreatment chamber has an ingenious structural design, which effectively reduces the power consumption and space occupation of devices, resulting in low manufacturing costs.

In one embodiment, the number of the chemical vapor deposition chamber is one, and in another embodiment, the number of the chemical vapor deposition chamber is two or more. That is, multiple chemical vapor deposition chambers share one multifunctional wafer pretreatment chamber, which can fully utilize the advantages of the multifunctional wafer pretreatment chamber, facilitating further miniaturization of devices and reducing device power consumption.

In summary, the present disclosure discloses a multifunctional wafer pretreatment chamber and a chemical vapor deposition device. The ingenious structural design of the present disclosure integrates the heating and cooling functions in different locations within the same chamber. Therefore, the device functions are more integrated, and the interference between the two functions (such as the heat spreading from the heating area to the cooling area) is minimized. This improves the wafer heating and cooling efficiency, increases the device output, and reduces the power consumption and manufacturing costs of devices. Moreover, the improved structural design also enhances heating uniformity, and reduces the problems of wafer warping, uneven film deposition thickness, wafer deformation and slippage caused by uneven heating. Therefore, the present disclosure effectively overcomes various shortcomings in the existing technology and has high industrial utilization value.

The above-mentioned embodiments are merely illustrative of the principle and effects of the present disclosure instead of restricting the scope of the present disclosure. Any person skilled in the art may modify or change the above embodiments without violating the principle of the present disclosure. Therefore, all equivalent modifications or changes made by those who have common knowledge in the art without departing from the spirit and technical concept disclosed by the present disclosure shall be still covered by the claims of the present disclosure.

1. A multifunctional wafer pretreatment chamber, comprising a cavity, a wafer carrier device, a preheating device, a thermal conductive device, a cooling device, a first driving device, a second driving device, and a controller; wherein the cavity is provided with at least one gate; wherein the wafer carrier device is located in the cavity and comprises a carrier tray and a plurality of supporting pins, the carrier tray is provided with a plurality of containing holes, and each of the plurality of supporting pins is disposed in one of the plurality of containing holes; wherein the first driving device is connected with the plurality of supporting pins; wherein the thermal conductive device is located below the preheating device and above a wafer to be treated, and the thermal conductive device comprises a thermal conductive plate and a thermal insulation coating; wherein dimensions of the thermal conductive plate are consistent with those of the wafer, a plurality of thermal conductive holes are distributed on the thermal conductive plate at intervals, the plurality of thermal conductive holes penetrate the thermal conductive plate, and the thermal insulation coating covers surfaces of the thermal conductive plate not penetrated by the heat conduction holes; wherein the preheating device comprises a lamp plate and two or more heating lamps, the lamp plate comprises a plate-surface portion and a shielding portion, the heating lamps are fixed to a bottom surface of the plate-surface portion, a first end of the shielding portion is connected with an edge of the plate-surface portion, and a second end of the shielding portion extends to be in contact with an edge of the thermal conductive plate; wherein the second driving device is connected with the lamp plate and configured to drive the preheating device to rotate; wherein the cooling device comprises a cooling pipe located in the carrier tray, and the cooling device is in communication with a cooling source; wherein the controller is connected to the first driving device and the second driving device; wherein
when the multifunctional wafer pretreatment chamber is in a preheating mode, the first driving device drives the supporting pins to ascend to support the wafer under the control of the controller, the preheating device is started, and light emitted by the heating lamps reaches a surface of the wafer through the thermal conductive holes, so as to heat the wafer;
when the multifunctional wafer pretreatment chamber is in a cooling mode, the first driving device drives the supporting pins to descend under the control of the controller, the wafer is placed on the carrier tray, and the cooling device is started.

2. The multifunctional wafer pretreatment chamber according to claim 1, wherein a surface of the lamp plate facing the thermal conductive plate and/or a surface of the shielding portion adjacent to the heating lamps is provided with a reflective thermal insulation coating.

3. The multifunctional wafer pretreatment chamber according to claim 1, wherein the at least one gate comprises a first gate and a second gate, and the controller is connected to the first gate and the second gate; wherein when the wafer enters the cavity through the first gate, the controller controls the preheating device to start and the supporting pins to ascend, and when the wafer enters the cavity through the second gate, the controller controls the cooling device to start and the supporting pins to descend.

4. The multifunctional wafer pretreatment chamber according to claim 1, wherein a groove is formed in the carrier tray, a cooling pipe is disposed on a side surface and a bottom surface of the groove, and the wafer to be treated is placed in the groove.

5. The multifunctional wafer pretreatment chamber according to claim 1, wherein a top surface of each supporting pin is an inclined surface, and when the multifunctional wafer pretreatment chamber is in the preheating mode, the top surface of each supporting pin is in contact with an edge of the wafer.

6. The multifunctional wafer pretreatment chamber according to claim 1, wherein the multifunctional wafer pretreatment chamber further comprises a third driving device connected to the carrier tray and electrically connected to the controller, and configured to drive the carrier tray to reciprocatively rotate and/or ascend and/or descend.

7. The multifunctional wafer pretreatment chamber according to claim 1, wherein the multifunctional wafer pretreatment chamber further comprises a temperature measuring device, which is located in the cavity and electrically connected with the controller; wherein the controller is electrically connected with the heating lamps, and when the temperature measuring device detects that temperatures in different surface areas of the wafer are different, the controller is configured to adjust power of the heating lamps, respectively.

8. The multifunctional wafer pretreatment chamber according to claim 1, wherein the multifunctional wafer pretreatment chamber further comprises an auxiliary thermal insulation device and a fourth driving device connected with the auxiliary thermal insulation device; wherein the auxiliary thermal insulation device is located in the cavity, the fourth driving device is electrically connected with the controller, and when the multifunctional wafer pretreatment chamber is in the preheating mode, under the control of the controller, the fourth driving device drives the auxiliary thermal insulation device to wrap around a space between the thermal conductive device and the carrier tray to prevent heat loss.

9. A chemical vapor deposition device, comprising at least one chemical vapor deposition chamber and the multifunctional wafer pretreatment chamber according to claim 1, wherein the chemical vapor deposition chamber is connected with the multifunctional wafer pretreatment chamber.

10. The chemical vapor deposition device according to claim 9, wherein the at least one chemical vapor deposition chamber comprises two or more chemical vapor deposition chambers.
